(19) United States
(12) Patent Application Publication
(10) Pub. No.: US 2011/0149538 A1
(43) Pub. Date: Jun. 23, 2011

(54) Electronic Devices with Embedded Electromagnetic Materials and Process of Making the Same

(76) Inventors: Ji Cui, Aurora, IL (US); Nie Luo, Savoy, IL (US)

(21) Appl. No.: 12/885,452

(22) Filed: Sep. 18, 2010

Related U.S. Application Data
(60) Provisional application No. 61/260,018, filed on Nov. 11, 2009.

(51) Int. Cl. H05K 1/18; H05K 9/00; H05K 1/09; H05K 1/02; B82Y 99/00

(52) U.S. Cl. 361/761; 174/260; 174/257; 174/256; 174/250; 977/932

(57) ABSTRACT

This provisional application relates to reducing electromagnetic interferences (EMI) using embedded magnetic material in a printable circuit board (PCB) and the applications thereof.

### PRIORITY

This application claims the priority of provisional U.S. application 61/260018

### BACKGROUND

EMI (electromagnetic interferences) of electronics are becoming more and more severe with the increase of frequencies of electronic devices and the increase of the number of mobile electronic devices. The common method of dealing with EMI is to shield device or components with conductive materials. However, in most cases, conductive materials only reflect the EMI energy, which may cause unintended problems at other devices or components. The best way to deal with EMI is to absorb undesired high frequency EM energy at its source. EMI suppression tapes, beads, and cylinders have been used to reduce EMI of active devices, wires, and cables. One common material is Ferrite beads. They are inductors used as a passive low-pass filter. The wire over the ferrite bead results in a high impedance for high-frequency signals, attenuating high frequency EMI electronic noise. The absorbed energy is converted to heat and dissipated by the ferrite.

For a typical ferrite ring, the wire is simply wrapped around the core through the center. Clamp-on cores are also available, which can be attached without wrapping the wire at all. However, with PCBs becoming more compact and complex, it is desirable to have EMI suppression function right in the PCB itself, absorbing the EM noise generated at that location and prevent the interferences at the source rather than absorbing the EM noise at a distance. To the best of our knowledge, there has been no report on adding magnetic EMI suppression material, especially ferrites, into embedded PCB dielectric material for this purpose.

### BRIEF DESCRIPTION OF THE DRAWINGS

FIG. 1, General illustration of a circuit making process

FIG. 2, illustration of the risks of using reactive components in dielectric layer during the circuit making process.

FIG. 3: illustration of a multilayer structure with chemical protection layer which chemically insulate the reactive filler from reacting with corrosive circuit making solutions

FIG. 4: illustration of an etched circuit that contains functional reactive components and chemical protection layer.

### DETAILED DESCRIPTION

The key idea is to add magnetic EMI suppression material into printed circuit board. The most efficient way to embed this material into the PCB as part of the dielectric layer, on which conductive layers, which is typically copper, are laminated and etched to form circuits. A PCB can use one or multiple layers of the EMI suppression materials. The EMI material is generally used in the whole area of a PCB board for easy process. However, this invention does not preclude using this material only in part of the PCB board.

The most preferred material approach will be to blend powders of EMI suppression material with dielectric binder resin like epoxy, acrylate, to form a composite material. The composite material can be formulated to function as the PCB dielectric layer. Another approach is to use pure magnetic EMI suppression material or magnetic EMI suppression material based composite material as an additional layer as part of multilayer dielectric structure to make an overall effective dielectric layer attached to one or two conductive layers. For example, one can make a ceramic magnetic EMI suppression layer and coat or laminate dielectric polymer resin on its surface, and use the multilayer film as an effective dielectric layer for PCB, another example will be depositing a layer of EMI suppression material on the surface of dielectric film or conductive film through coating or physical vapor deposition.

The most common magnetic EMI suppression materials are Ferrites. There are many kinds of ferrites. Different ferrites can be used to target different wavelengths of EM noise. Ni and Ni alloy, Fe and Fe alloy are also common EMI suppression materials. The composite material can be tailored to absorb different wavelengths of EM energy by choosing different magnetic EMI suppression material or a combination of different magnetic EMI suppression materials.

Another common type of magnetic materials for EMI suppression are garnets, which include but are not limited to Y—Fe—O (YIG), rare earth garnets like Al—Dy—O (Dy₃Al₅O₁₂), Dy—Ga—O (Dy₃Ga₅O₁₂), Eu—Ga—O (Eu₃Ga₅O₁₂), Ga—Gd—O (Gd₃Ga₅O₁₂), Ga—O—Sm (Sm₃Ga₅O₁₂), and Ga—O—Yb (Yb₃Ga₅O₁₂).

The EMI suppression material can be used in a dielectric layer to provide EMI suppression properties for that layer. It can also be added into another embedded device to provide EMI suppression functionalities for that device. For example, it can be added in embedded capacitors to absorb EMI radiation of a certain frequency range. It can also be added to over-voltage protection layer to give additional EMI absorption properties. Therefore, it can be a component in a multifunctional layer.

The EMI suppression magnetic material, especially ferrite based oxide and ceramics, can be powders of sphere, needle, plate, irregular, and any shape. The size need to be small to fit the composite and PCB related processes, such as lamination, via drilling. Different composite layer thicknesses require different particle sizes. General rule is that the D90 need to be smaller than the composite layer thickness.

Even though the invention focuses on using composite magnetic EMI suppression material, it is also within the scope of the inventory to use one or more layer of pure magnetic EMI suppression materials in the dielectric layer as a part of multilayer dielectric structure in PCB.

The organic binder resin is one or a combination of organic materials that can solidify or crosslink into a strong solid structure which holds a variety of other components other than the said organic material together to form a stable solid mixture. It can be selected from epoxies, cyanate ester, polyester, polytetrafluoroethylene, PVDF, polyphenylene ether, and other polymers that are thermally stable under PCB process conditions.

In the binder formulation, there can be a variety of other additives. For example, curing agents and curing accelerators can cure the binder, dispersion agents can help the dispersion of fillers, defoamer can reduce the foam in process, rheology control agents can tailor the viscosity for process needs, resin modifiers, such as plasticizers or crosslinkers, can make the cured resin stronger or more flexible, thermal stabilizer can make the resin stable at high temperature, adhesion promoter can increase the bonding between polymer film and the conductive layer.

The conductive layers are usually copper foil. Other conductive materials, selected from a list comprising aluminum, nickel, silver, conductive polymer, conductive polymer composite, conductive paste, carbon nanotube based conductive composite, can also be used. The surface of copper foil can be treated with other metal elements, metal oxides, silanes, and organic adhesion promoting agents to improve adhesion to organic substrate or to increase capacitance of the structure. Common surface treatment metal comprises nickel, chrome, titanium, tungsten, tin, phosphorus, sulfur, their oxides, and a combination thereof. The metal foil surface can be mechanically or electro-chemically polished or be etched to modify surface roughness. Conductive composites, such as carbon-nanotube composites can be deposited onto the dielectric layer as a patterned circuit using photo lithograpy or screen printing.

To strengthen the multilayer structure and to adjust coefficient of thermal expansion (CTE), s, a plastic film material or a fibrous material can be added in the dielectric layer. The fibrous material can be selected from a list comprising: aramid fiber, non-woven or woven aramid fiber cloth, glass fiber, non-woven or woven glass cloth, Nomex™ fiber, woven or non-woven Nomex™ cloth. These reinforcement materials can be used to make free standing dielectric laminate, which will be laminated with copper foils in panel form. They can also be applied directly into a polymer layer of the multilayer structure in roll to roll format.

The copper/multilayer dielectric material/copper device can go through typical micro-electronics processes to generate patterned conductive traces on dielectric materials, comprising, Via processes, plating, photo imaging, lamination. Details of those processes can be found in Print Circuit Board Handbook, Sixth edition, Edited by Clyde F. Coombs. The high capacitance of multilayered dielectric material will be used as embedded capacitor in the micro-electronic devices.

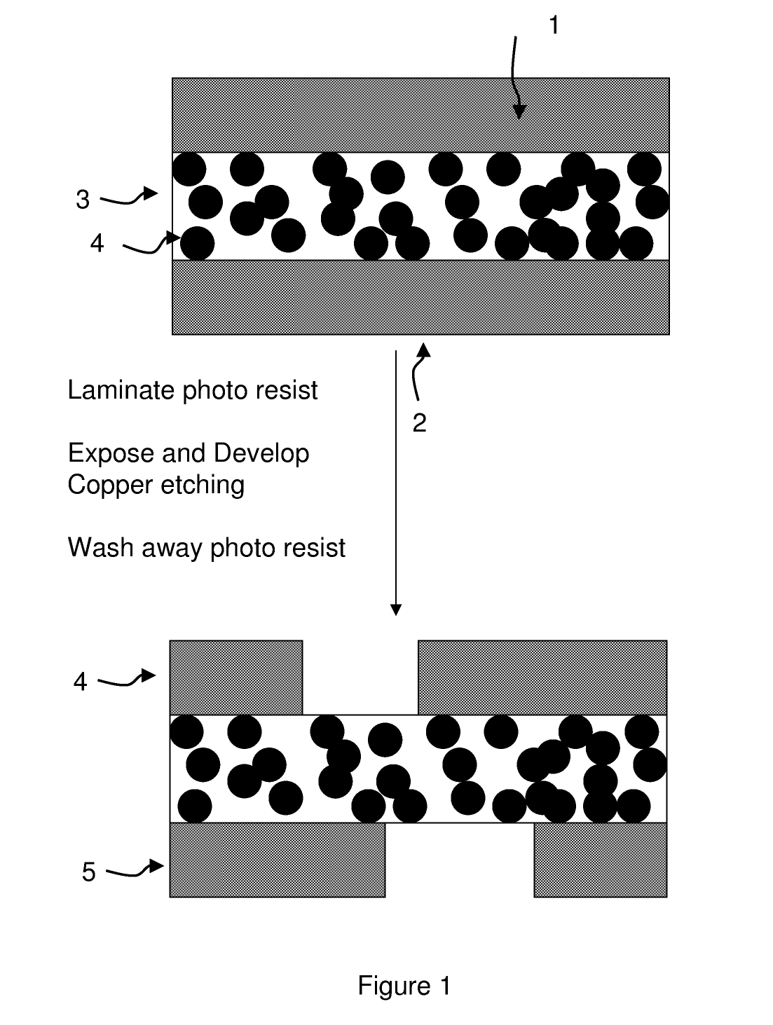

In PCB manufacture, circuit making process usually involves copper etching or copper plating process. FIG. 1 illustrated the circuit making process using etching. 1 and 2 are copper layers; 3 is the dielectric layer that contain fillers 4. After laminate photoresists, expose to designed pattern, develop, etching, and wash away remaining photoresist, copper circuit layer, illustrated 4 and 5, are formed on dielectric layer surface. The illustrate shows two layers of circuit on one dielectric layer. PCBs usually have multiple layers of circuit and multiple layers of dielectric layer.

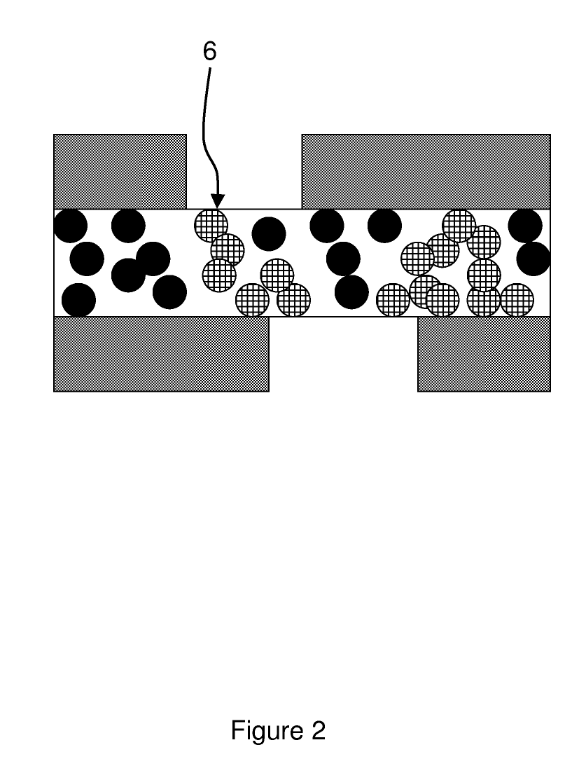

Some ferrite materials are reactive to the chemicals used in the PCB manufacture processes. Both copper etching solution and plating solution are strong acids. The copper etching solution also has oxidizing agents. If the solution reacts with the fillers in the dielectric layer, it can cause many kinds of defects, such as pinholes, undercut, delaminations. The situation is worse with high loading of the reactive components, especially when they need to reach percolation threshold. This situation is illustrated in FIG. 2. When a component is reactive with the copper etching solution, the component can be etched away during the circuit forming process and cause voids. Void can trap corrosive or conductive solution, cause delaminations or undercuts.

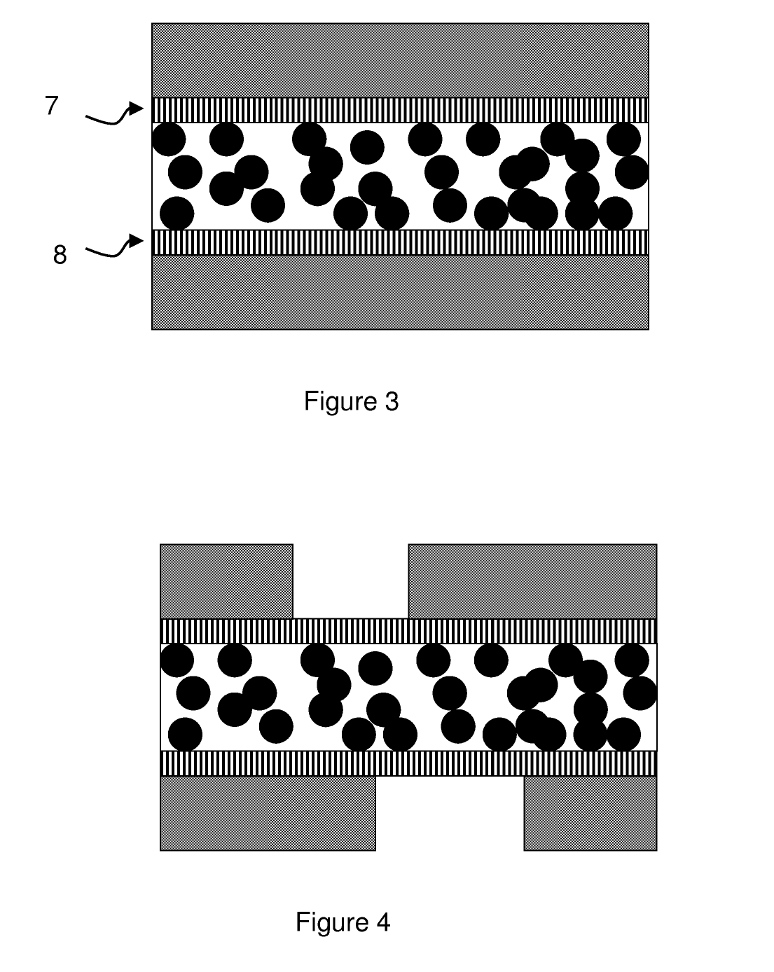

To prevent these problems, a protection layer can be added to the copper layer surface or to the dielectric layer surface. The structure is illustrated in FIG. 3. Layer 7 and 8 locate between the surface of conductive layers and the surface of functional dielectric layer that contains the reactive components. It prevents the chemical reaction between PCB processing chemicals and the reactive components in the composite layer. This method is not limited to embedded EMI suppression devices that have ferrite materials. It can be used for other embedded applications, like capacitors, in which reactive metals, like aluminum, can be used, or embedded electrostatic discharge (ESD) protection devices. FIG. 4 illustrated the final etched copper circuits, the protective layer, and dielectric layer that contain the reactive filler. The multilayer serves as an effective dielectric layer, separating conductive circuit layers, in PCB. In this patent application, the multilayer, or other similar structures can be referred as dielectric layer in general.

The insulation layer can be applied on copper surface or on dielectric surface. It is more straightforward to apply it on copper surface. The protective layer is preferred to be less than 10 micron, more preferred to be less than 5 or even less than 1 micron. The exact lower limit will be determined by the specific etching and plating conditions, the chemical protection material, and the reactivity of the reactive component in the composite layer.

### EXAMPLES

### Example 1

150 um diameter copper wire of 13 cm long, embedded between two layer 70 micron thick 40% ferrite powder and epoxy binder resin composite materials. The test was carried out on a HP 4195A network/spectrum analyzer. Impedence was measured in a frequency range from 0.001 Hz to 500 MHz. Compare with baseline material, where a same diameter and same length wire is embedded between two layers of pure epoxy, the wire embedded among ferrite composite material shows about ˜5 dB attenuation in the frequency between 350 MHz to 500 MHz. This example demonstrates the EMI suppression effects on circuit traces that are directly attached to the surface of ferrite composite dielectric layer in PCB.

### Example 2

Energy loss caused by Ferrite across the thickness of dielectric layer.

In this experiment, two samples were made:

Sample 1: a 35 micron composite layer of Epoxy binder and 5% ferrite powder (by volume) and 13 micron thick fiber glass cloth. This layer composite material is sandwiched between two layers of copper.

Sample 2: a 40 micron composite layer of Epoxy and 40% ferrite powder and 13 micron think fiber glass cloth. This layer of composite material is sandwiched between two layers of copper.

The copper pads at the two sides of the composite dielectric material are connected to a network analyzer to measure the losses at frequency ranges between 1000 Hz and 1 MHz. The results show that the 5% (volume) ferrite sample has ˜0.03-0.06 losses, while the composite with 40% (volume) ferrite of has losses of about 0.12-0.24, a higher loss for higher ferrite contents. In comparison, a sample with a 35 micron composite layer of Epoxy and 48% aluminum powder and 13 micron think fiber glass cloth, was also tested as a blank. This sample shows average loss of only 0.02, in stark contrast to the high loss caused by the ferrite samples. The loss is defined approximately as the ratio between the imaginary and the real part of the complex dielectric constant. Because there is an induced electric field due to the time-dependent variation in magnetic induction due to the enhanced ferromagnetic (or ferrimagnetic) susceptibility due to the ferrite, the improvement in the AC dielectric loss due to ferrite is significant.

These experiments show that the EMI suppression layer can be effectively in PCB to suppress EMI radiations. It can be used in a selected layer or in many layers of PCB, such as attaching to power plane, to ground plain, to circuit layer that are connected to high frequency chip. It can be used for multiple layers or even all the layers. There are many different EMI suppression materials, different ferrite materials targeting absorptions at different electromagnetic frequencies. One can use a combination of different materials to control absorptions of a specific spectrum. It is also possible to use different EMI suppression materials in different PCB layers to achieve detailed control EMI of different circuits in a PCB. The EMI suppression layer can be further combined with one or multiple shielding layers of conductive materials to optimize the electromagnetic compatibilities (EMC). The combination of EMI suppression and EMI shielding can enhance EMC at specific locations for specific devices. There are many design options to use the EMI suppression composite layer in PCB board by adjusting the characteristic absorption wavelengths of the EMI suppression materials, the concentration of the EMI suppression materials, the thickness of the composite layer, the location of conductive layers, the sizes of conductive pad, the type of the circuits on the EMI control layer, etc.

Spatially speaking, the word “imbedded” means the composite dielectric layer reside in the PCB, including inner layer of a PCB or at the outer layers. This is to differentiate from conventional electronic components that are attached on top of PCB. It usually covers the whole area of a PCB board. However, one can exert special effort to make the material covering only a specific portion of a PCB.

A dielectric layer in this application can be one single layer of dielectric material of a multilayer of materials of homogeneous or heterogeneous materials that make the overall multilayer structure an effective dielectric layer sandwiched between conductive layers. The multilayer material can include insulation layer, protection layer, strengthening layer of film or fibers, and others.

1. An embedded electronic device in printed circuit board that consists of a dielectric layer between two patterned or unpatterned conductive layers, and the dielectric layer comprises EMI suppression magnetic material.

2. The device of claim 1 wherein the magnetic EMI suppression material comprises at least one of the pure elements, alloys or compounds of a metal selected from a list consisting of Ti, V, Cr, Mn, Fe, Co, Ni, Cu, Zn, La, Ce, Pr, Nd, Pm, Sm, Eu, Gd, Tb, Dy, Ho, Er, Tm, Yb, Lu.

3. The device of claim 1, wherein the magnetic EMI suppression material is a ferrite material.

4. The device of claim 1, wherein the magnetic EMI suppression material is a garnet material.

5. The device of claim 1, wherein a combination of EMI suppression materials are used to absorb a targeted spectrum of electromagnetic radiations.

6. The device of claim 1, wherein a conductive layer, a conductive pad, or conductive fillers are used in combination with the EMI suppression composite layer in PCB to provide electromagnetic compatibility properties.

7. The device of claim 1, wherein the dielectric layer comprises, in additional to magnetic EMI suppression material, components that provide other passive functionalities of capacitors, overvoltage protection devices, resistors, over-current protection devices, or passive filtering devices for certain frequencies.

8. The device of claim 7, wherein the said components comprise titanate ceramic powder, coated and uncoated conductive particles, particles with conductive domains, varistor particles, voltage switching composites materials, carbon nanotube, carbon black, or metal oxide.

9. A multilayer embedded electronic device that comprises
an embedded composite dielectric layer in printed circuit board that contains at least one component that is reactive to circuit etching or circuit plating chemicals used in the circuit making processes, and
at least one protective layer is used to separates the said composite dielectric layer from the conductive layer, and chemically protect the dielectric layer from the above said reactive chemicals in circuit making processes.

10. The multilayer embedded electronic device of claim 9, wherein the reactive component is selected from:
a. metals including aluminum, magnesium, iron,
b. metal oxides including doped or undoped zinc oxide, magnesium oxide, aluminum oxide, ferrous oxide, ferric oxide,
c. ceramics including ferrite, garnet.

11. The multilayer embedded passive electronic device of claim 9, wherein the device functions as: capacitors, EMI suppression devices, passive filtering device for certain frequencies, resistors, passive over voltage devices, or passive over current devices.
